(19) United States
(12) Patent Application Publication
(10) Pub. No.: US 2021/0234012 A1
(43) Pub. Date: Jul. 29, 2021

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Hiroshi ONO, Setagaya (JP); Yosuke KAJIWARA, Yokohama (JP); Masahiko KURAGUCHI, Yokohama (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 17/015,299

(22) Filed: Sep. 9, 2020

(30) Foreign Application Priority Data
Jan. 27, 2020 (JP) 2020-010729

(51) Int. Cl. H01L 29/417; H01L 29/20; H01L 29/205; H01L 29/778

(52) U.S. Cl. CPC H01L 29/41766; H01L 29/7786; H01L 29/205; H01L 29/2003

(57) ABSTRACT

According to one embodiment, a semiconductor device includes a first electrode, a second electrode, a third electrode, and a nitride member. A position of the third electrode in a first direction is between a position of the first electrode in the first direction and a position of the second electrode in the first direction. The nitride member includes a first nitride layer and a second nitride layer. The first nitride layer includes first, second, and third partial regions. The first electrode includes first, second, and third conductive portions, and a first conductive layer. The first, second, third conductive portions, and a portion of the second nitride layer are between the first partial region and the first conductive layer. The first, second, and third conductive portions are electrically connected to the first conductive layer. The second nitride layer includes a first region between the first and second conductive portions.

### CROSS-REFERENCE TO RELATED APPLICATIONS

This application is based upon and claims the benefit of priority from Japanese Patent Application No. 2020-010729, filed on Jan. 27, 2020; the entire contents of which are incorporated herein by reference.

### FIELD

Embodiments of the invention generally relate to a semiconductor device.

### BACKGROUND

For example, it is desirable to improve the characteristics of a semiconductor device such as a transistor or the like.

### BRIEF DESCRIPTION OF THE DRAWINGS

FIGS. 1A to 1C are schematic views illustrating a semiconductor device according to a first embodiment;

FIGS. 2A to 2D are schematic views illustrating the semiconductor device according to the first embodiment;

FIG. 3 is a schematic plan view illustrating the semiconductor device according to the first embodiment;

FIGS. 4A to 4C are schematic plan views illustrating semiconductor devices;

FIGS. 5A to 5C are schematic views illustrating a semiconductor device according to the first embodiment;

FIGS. 6A to 6D are schematic views illustrating semiconductor devices according to the first embodiment;

FIG. 7 is a graph illustrating a characteristic of the semiconductor device;

FIG. 8 is a schematic cross-sectional view illustrating a semiconductor device according to a second embodiment; and

FIG. 9 is a schematic cross-sectional view illustrating a semiconductor device according to the second embodiment.

### DETAILED DESCRIPTION

According to one embodiment, a semiconductor device includes a first electrode, a second electrode, a third electrode, and a nitride member. A position of the third electrode in a first direction is between a position of the first electrode in the first direction and a position of the second electrode in the first direction. The first direction is from the first electrode toward the second electrode. The nitride member includes a first nitride layer including Alₓ₁Ga₁₋ₓ₁N (0≤x1<1), and a second nitride layer including Alₓ₂Ga₁₋ₓ₂N (x1<x2<1). The first nitride layer includes a first partial region, a second partial region, and a third partial region. A direction from the first partial region toward the first electrode is along a second direction crossing the first direction. A direction from the second partial region toward the second electrode is along the second direction. A direction from the third partial region toward the third electrode is along the second direction. The first electrode includes a first conductive portion, a second conductive portion, a third conductive portion, and a first conductive layer. The first conductive portion, the second conductive portion, the third conductive portion, and a portion of the second nitride layer are between the first partial region and the first conductive layer in the second direction. The first conductive portion, the second conductive portion, and the third conductive portion are electrically connected to the first conductive layer. A position in the first direction of the first conductive portion is between a position in the first direction of the third conductive portion and the position in the first direction of the third electrode. A position in the first direction of the second conductive portion is between the position in the first direction of the third conductive portion and the position in the first direction of the third electrode. The second nitride layer includes a first region between the first conductive portion and the second conductive portion.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

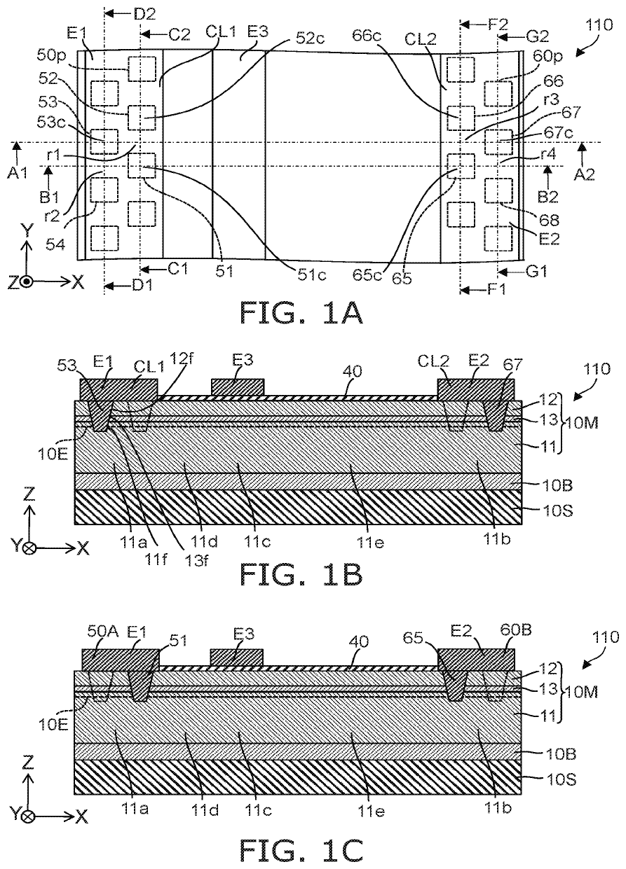

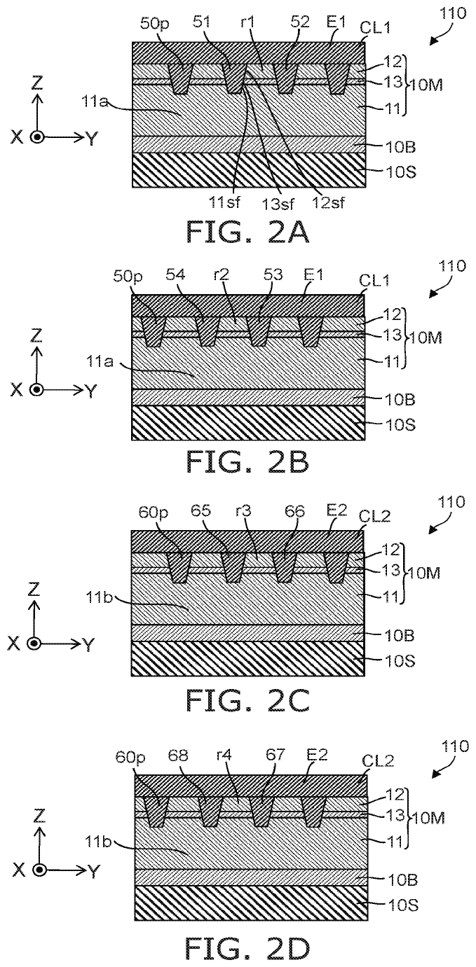

FIGS. 1A to 1C and FIGS. 2A to 2D are schematic views illustrating a semiconductor device according to a first embodiment.

FIG. 1A is a plan view. FIG. 1B is a line A1-A2 cross-sectional view of FIG. 1A. FIG. 1C is a line B1-B2 cross-sectional view of FIG. 1A. FIG. 2A is a line C1-C2 cross-sectional view of FIG. 1A. FIG. 2B is a line D1-D2 cross-sectional view of FIG. 1A.

As shown in FIGS. 1A and 1B, the semiconductor device 110 according to the embodiment includes a first electrode E1, a second electrode E2, a third electrode E3, and a nitride member 10M. In the example, the semiconductor device 110 includes an insulating member 40. The semiconductor device 110 may include a base body 10S and a buffer layer 10B.

The direction from the first electrode E1 toward the second electrode E2 is taken as a first direction. The first direction is taken as an X-axis direction. One direction perpendicular to the X-axis direction is taken as a Z-axis direction. A direction perpendicular to the X-axis direction and the Z-axis direction is taken as a Y-axis direction.

The position of the third electrode E3 in the first direction (the X-axis direction) is between the position of the first electrode E1 in the first direction and the position of the second electrode E2 in the first direction. For example, at least a portion of the third electrode E3 may be between at least a portion of the first electrode E1 and at least a portion of the second electrode E2 in the X-axis direction.

The nitride member 10M includes a first nitride layer 11 and a second nitride layer 12. As shown in FIG. 1B, the nitride member 10M may further include a third nitride layer 13.

The first nitride layer 11 includes Alₓ₁Ga₁₋ₓ₁N (0≤x1<1). The Al composition ratio in the first nitride layer 11 is, for example, not less than 0 and not more than 0.1. The first nitride layer 11 is, for example, a GaN layer.

As shown in FIG. 1B, the first nitride layer 11 includes a first partial region 11a, a second partial region 11b, and a third partial region 11c. The third partial region 11c is between the first partial region 11a and the second partial region lib in the first direction (the X-axis direction).

The direction from the first partial region 11a toward the first electrode E1 is along a second direction. The second direction crosses the first direction. The second direction is, for example, the Z-axis direction. The direction from the second partial region 11b toward the second electrode E2 is along the second direction. The direction from the third partial region 11c toward the third electrode E3 is along the second direction.

As shown in FIG. 1B, the first nitride layer 11 may include a fourth partial region 11d and a fifth partial region 11e. The fourth partial region 11d is between the first partial region 11a and the third partial region 11c in the first direction (the X-axis direction). The fifth partial region 11e is between the third partial region 11c and the second partial region 11b in the first direction.

The second nitride layer 12 includes Alₓ₂Ga₁₋ₓ₂N (x1<x2<1). The Al composition ratio in the second nitride layer 12 is, for example, greater than 0.1 and less than 1. The second nitride layer 12 is, for example, an AlGaN layer.

For example, a portion of the second nitride layer 12 is between the first nitride layer 11 and the first electrode E1 in the second direction (e.g., the Z-axis direction). For example, another portion of the second nitride layer 12 is between the first nitride layer 11 and the first electrode E1 in the second direction.

For example, the buffer layer 10B may be provided on the base body 10S. The buffer layer 10B is, for example, a nitride layer. The first nitride layer 11 is provided on the buffer layer 10B. The second nitride layer 12 is provided on the first nitride layer 11.

A carrier region 10E is formed at the second nitride layer 12 side of the first nitride layer 11. The carrier region 10E is, for example, a two-dimensional electron gas.

The first electrode E1 functions as one of a source electrode or a drain electrode. The second electrode E2 functions as the other of the source electrode or the drain electrode. The third electrode E3 functions as a gate electrode. A current that flows between the first electrode E1 and the second electrode E2 can be controlled according to the potential of the third electrode E3. The semiconductor device 110 is, for example, a HEMT (High Electron Mobility Transistor).

In the example shown in FIG. 1A, the distance between the first electrode E1 and the third electrode E3 is less than the distance between the third electrode E3 and the second electrode E2. In the embodiment, the distance between the first electrode E1 and the third electrode E3 may be greater than the distance between the third electrode E3 and the second electrode E2.

As shown in FIGS. 1B and 1C, at least a portion of the insulating member 40 is provided between the third electrode E3 and the nitride member 10M. At least a portion of the insulating member 40 functions as a gate insulating film.

As shown in FIGS. 1A to 1C, the first electrode E1 includes a first conductive portion 51, a second conductive portion 52, a third conductive portion 53, and a first conductive layer CL1.

As shown in FIGS. 1B, 1C, and 2A, the first conductive portion 51, the second conductive portion 52, the third conductive portion 53, and a portion of the second nitride layer 12 are between the first partial region 11a and the first conductive layer CL1 in the second direction (the Z-axis direction). The first conductive portion 51, the second conductive portion 52, and the third conductive portion 53 are electrically connected to the first conductive layer CL1.

As shown in FIG. 1A, the position in the first direction (the X-axis direction) of the first conductive portion 51 is between the position in the first direction of the third conductive portion 53 and the position in the first direction of the third electrode E3. The position in the first direction of the second conductive portion 52 is between the position in the first direction of the third conductive portion 53 and the position in the first direction of the third electrode E3. For example, the direction from the first conductive portion 51 toward the second conductive portion 52 is along the Y-axis direction.

As shown in FIGS. 1A and 2A, the second nitride layer 12 includes a first region r1. The first region r1 is between the first conductive portion 51 and the second conductive portion 52.

Due to such a configuration, the first region r1 corresponds to a current path between the third conductive portion 53 and the second electrode E2. The first region r1 that corresponds to another current path is obtained in addition to the current path between the first conductive portion 51 and the second electrode E2 and the current path between the second conductive portion and the second electrode E2. For example, a low on-resistance is obtained thereby. A semiconductor device can be provided in which the characteristics can be improved. Examples of the current paths are described below.

As shown in FIG. 1A, the first electrode E1 may further include a fourth conductive portion 54. The fourth conductive portion 54 is electrically connected to the first conductive layer CL1. The fourth conductive portion 54 is between the first partial region 11a and the first conductive layer CL1 in the second direction (the Z-axis direction). The position in the first direction (the X-axis direction) of the first conductive portion 51 is between the position in the first direction of the fourth conductive portion 54 and the position in the first direction of the third electrode E3. The position in the first direction of the second conductive portion 52 is between the position in the first direction of the fourth conductive portion 54 and the position in the first direction of the third electrode E3. For example, the direction from the fourth conductive portion 54 toward the third conductive portion 53 is along the Y-axis direction.

As shown in FIGS. 1A and 2B, the second nitride layer 12 includes a second region r2. The second region r2 is between the third conductive portion 53 and the fourth conductive portion 54.

For example, the third conductive portion 53 includes a side surface that faces the second region r2. The fourth conductive portion 54 includes a side surface that faces the second region r2. By providing the second region r2, current paths are formed between the second electrode E2 and these side surfaces. An even lower on-resistance is obtained thereby.

As shown in FIG. 1A, the first electrode E1 includes multiple conductive portions 50p. The multiple conductive portions 50p include the first to fourth conductive portions 51 to 54, etc. The current paths are increased by providing the multiple conductive portions 50p. The on-resistance can be reduced.

For example, the multiple conductive portions 50p (e.g., the first conductive portion 51, the second conductive portion 52, the third conductive portion 53, etc.) are not electrically connected by a conductive member other than the first conductive layer CL1. Thereby, the current paths are not broken by another conductive member. The on-resistance can be effectively reduced.

For example, another conductive member is not between the multiple conductive portions 50p. For example, another conductive member that contacts a region between the first nitride layer and the second nitride layer is not provided between the first conductive portion 51 and the third electrode E3 and between the second conductive portion 52 and the third electrode E3. For example, the carrier region 10E is formed at the vicinity of the region between the first nitride layer and the second nitride layer. Another conductive member does not break the current paths because another conductive member that contacts the carrier region 10E is not provided. The on-resistance can be effectively reduced.

For example, a current flows between the multiple conductive portions 50p and the second electrode E2 via the carrier region 10E. Therefore, by increasing the number of the multiple conductive portions 50p, the contact length (surface area) between the carrier region 10E and the multiple conductive portions 50p is increased. In such a case, the widths of the current paths can be effectively increased because the current path between the second electrode E2 and each of the multiple conductive portions 50p is not broken by another conductive member (or insulating member).

In the embodiment, the multiple conductive portions 50p (e.g., the first conductive portion 51, the second conductive portion 52, the third conductive portion 53, etc.) are island-like. The multiple conductive portions 50p are mutually independent.

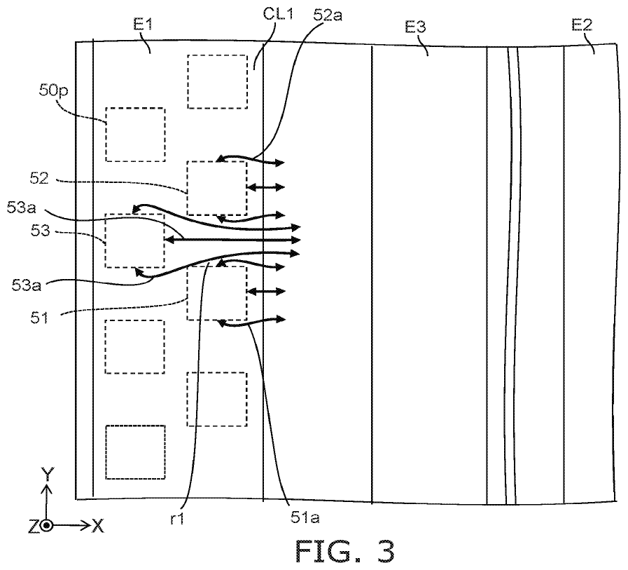

FIG. 3 is a schematic plan view illustrating the semiconductor device according to the first embodiment.

FIG. 3 illustrates current paths between the first electrode E1 and the second electrode E2. For example, a current can flow along a current path 51a between the second electrode E2 and the side surface of the first conductive portion 51. For example, a current can flow along a current path 52a between the second electrode E2 and the side surface of the second conductive portion 52. For example, a current path 53a between the second electrode E2 and the side surface of the third conductive portion 53 can reach the second electrode E2 by passing through the first region r1 between the first conductive portion 51 and the second conductive portion 52.

In the embodiment, the current path 53a that is connected to the third conductive portion 53 effectively reaches the second electrode E2. The on-resistance can be effectively reduced because there are many current paths.

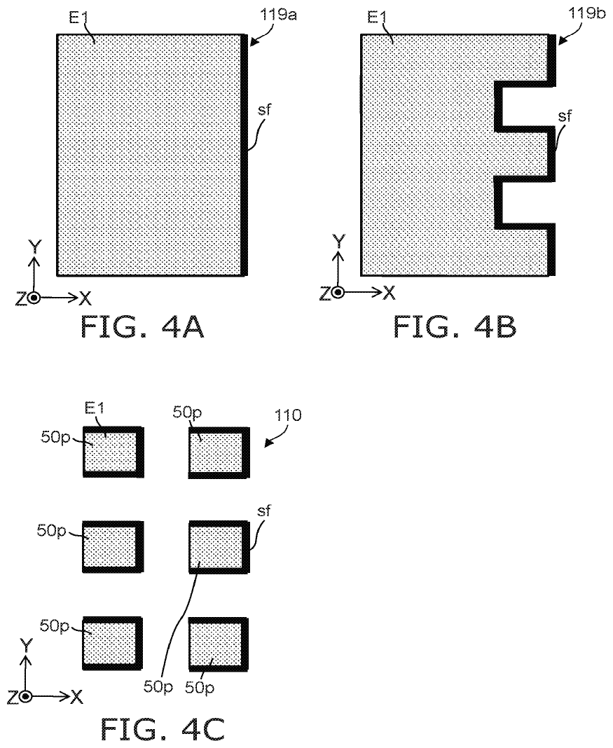

FIGS. 4A to 4C are schematic plan views illustrating semiconductor devices.

These drawings illustrate the first electrode E1. In these figures, the third electrode E3 and the second electrode E2 are rightward of the first electrode E1.

In a semiconductor device 119a of a first reference example illustrated in FIG. 4A, the first electrode E1 is one continuous body, and the multiple conductive portions 50p are not provided. In the semiconductor device 119a, a side surface sf of the first electrode E1 at which a current path is formed has, for example, a straight-line shape.

In a semiconductor device 119b of a second reference example illustrated in FIG. 4B, the first electrode E1 has an unevenness. The unevenness protrudes or recedes in the X-axis direction. In the semiconductor device 119b, the side surface sf of the first electrode E1 at which current paths are formed has, for example, an uneven configuration. The length of the side surface sf in the semiconductor device 119b is greater than the length of the side surface sf in the semiconductor device 119a.

In the semiconductor device 110 according to the embodiment illustrated in FIG. 4C, the first electrode E1 includes the multiple island-like conductive portions 50p. In the semiconductor device 110, current paths are formed at the side surfaces sf of the multiple conductive portions 50p included in the first electrode E1. The length of the side surface sf in the semiconductor device 110 is greater than the length of the side surface sf in the semiconductor device 119b.

For example, the contact resistance of the semiconductor device 119b is 0.57 times the contact resistance of the semiconductor device 119a. The contact resistance of the semiconductor device 110 is, for example, 0.42 times the contact resistance of the semiconductor device 119a. Thus, according to the embodiment, a low contact resistance is obtained.

In the example shown in FIG. 4C, the multiple conductive portions 50p that are provided in the first electrode E1 include groups in two columns along the Y-axis direction. In the embodiment, groups of three or more columns may be provided. An even lower contact resistance is obtained.

As shown in FIG. 2A, the first partial region 11a of the first nitride layer 11 includes a first side surface 11sf. The first side surface 11sf crosses a third direction crossing a plane including the first direction (the X-axis direction) and the second direction (the Z-axis direction). The third direction is, for example, the Y-axis direction. The first conductive portion 51 contacts the first side surface 11sf.

As shown in FIG. 2A, a portion of the second nitride layer 12 includes a second side surface 12sf. The second side surface 12sf crosses the third direction (the Y-axis direction). The first conductive portion 51 contacts the second side surface 12sf.

The multiple conductive portions 50p can more stably contact the carrier region 10E because the multiple conductive portions 50p such as the first conductive portion 51, etc., contact the side surfaces of the first nitride layer 11 and the second nitride layer 12.

As shown in FIGS. 1B and 1C, the semiconductor device 110 may further include the third nitride layer 13. The third nitride layer 13 includes Alₓ₃Ga₁₋ₓ₃N (x2<x3≤1). The Al composition ratio in the third nitride layer 13 is, for example, 0.7 or more. The third nitride layer 13 is, for example, an AlN layer.

The third nitride layer 13 is between the first nitride layer 11 and the second nitride layer 12. By providing the third nitride layer 13, for example, the carrier concentration of the carrier region 10E can be increased. For example, high mobility is obtained. The thickness of the third nitride layer 13 is, for example, 3 nm or less. The thickness is the length along the Z-axis direction, which corresponds to the second direction.

In the embodiment, the multiple conductive portions 50p (e.g., the first conductive portion 51, the second conductive portion 52, the third conductive portion 53, etc.) extend through the third nitride layer 13 along the second direction (the Z-axis direction). Thereby, the multiple conductive portions 50p are stably connected to the carrier region 10E even when the third nitride layer 13 is provided.

As shown in FIG. 2A, the third nitride layer 13 includes a third side surface 13sf. The third side surface 13sf crosses the third direction (e.g., the Y-axis direction). The multiple conductive portions 50p (e.g., the first conductive portion 51, etc.) contacts the third side surface 13sf.

As shown in FIG. 1B, the first partial region 11a of the first nitride layer 11 includes a first surface 11f. The first surface 11f crosses the first direction (the X-axis direction). The position of the first surface 11f in the first direction is between the position of the third conductive portion 53 in the first direction and the position of the third electrode E3 in the first direction. The third conductive portion 53 contacts the first surface 11f.

As shown in FIG. 1B, a portion of the second nitride layer 12 includes a second surface 12f. The second surface 12f crosses the first direction (the X-axis direction). The position of the second surface 12f in the first direction is between the position of the third conductive portion 53 in the first direction and the position of the third electrode E3 in the first direction. The third conductive portion 53 contacts the second surface 12f.

As shown in FIG. 1B, the third nitride layer 13 includes a third surface 13f. The third surface 13f crosses the first direction (the X-axis direction). The position of the third surface 13f in the first direction is between the position of the third conductive portion 53 in the first direction and the position of the third electrode E3 in the first direction. The third conductive portion 53 contacts the third surface 13f.

For example, the third conductive portion 53 can be stably connected with the carrier region 10E because the third conductive portion 53 contacts the first surface 11f, the second surface 12f, and the third surface 13f.

As shown in FIG. 1A, the center of the third conductive portion 53 in the third direction (e.g., the Y-axis direction) is taken as a third center 53c. The center of the first conductive portion 51 in the third direction is taken as a first center 51c. The center of the second conductive portion 52 in the third direction is taken as a second center 52c. In the example, the position in the third direction of the third center 53c is between the position in the third direction of the first center 51c and the position in the third direction of the second center 52c. The first region r1 that corresponds to a current path is between the third conductive portion 53 and the second electrode E2 in the X-axis direction. A low contact resistance is more easily obtained.

As shown in FIGS. 1A, 1B, 2C, and 2D, the second electrode E2 includes a fifth conductive portion 65, a sixth conductive portion 66, a seventh conductive portion 67, and a second conductive layer CL2. The fifth conductive portion 65, the sixth conductive portion 66, the seventh conductive portion 67, and another portion of the second nitride layer 12 are between the second partial region 11b and the second conductive layer CL2 in the second direction (the Z-axis direction). The fifth conductive portion 65, the sixth conductive portion 66, and the seventh conductive portion 67 are electrically connected to the second conductive layer CL2.

The position in the first direction (the X-axis direction) of the fifth conductive portion 65 is between the position in the first direction of the seventh conductive portion 67 and the position in the first direction of the third electrode E3. The position in the first direction of the sixth conductive portion 66 is between the position in the first direction of the seventh conductive portion 67 and the position in the first direction of the third electrode E3. For example, the direction from the fifth conductive portion 65 toward the sixth conductive portion 66 is along the Y-axis direction.

As shown in FIGS. 1A and 2C, the second nitride layer 12 includes a third region r3. The third region r3 is between the fifth conductive portion 65 and the sixth conductive portion 66. For example, the third region r3 corresponds to a current path between the seventh conductive portion 67 and the first electrode E1. By applying such a configuration to the second electrode E2, the contact resistance of the second electrode E2 can be reduced.

For example, the fifth conductive portion 65, the sixth conductive portion 66, and the seventh conductive portion 67 are not electrically connected to a conductive member other than the second conductive layer CL2. For example, another conductive member that contacts a region between the first nitride layer 11 and the second nitride layer 12 is not provided between the fifth conductive portion 65 and the third electrode E3 and between the sixth conductive portion 66 and the third electrode E3. For example, the fifth conductive portion 65, the sixth conductive portion 66, and the seventh conductive portion 67 are island-like. By such a configuration, a lower contact resistance is easily obtained.

When the third nitride layer 13 is provided, for example, the fifth conductive portion 65, the sixth conductive portion 66, and the seventh conductive portion 67 extend through the third nitride layer 13 along the second direction (the Z-axis direction). For example, the fifth conductive portion 65, the sixth conductive portion 66, and the seventh conductive portion 67 contact the third nitride layer 13.

As shown in FIG. 1A, the second electrode E2 includes multiple conductive portions 60p. The multiple conductive portions 60p include the fifth conductive portion 65, the sixth conductive portion 66, and the seventh conductive portion 67. The multiple conductive portions 60p may include an eighth conductive portion 68. The eighth conductive portion 68 is electrically connected to the second conductive layer CL2. As shown in FIG. 2D, the eighth conductive portion 68 is between the second partial region 11b and the second conductive layer CL2 in the second direction (the Z-axis direction).

As shown in FIG. 1A, the position in the first direction (the X-axis direction) of the fifth conductive portion 65 is between the position in the first direction of the eighth conductive portion 68 and the position in the first direction of the third electrode E3. The position in the first direction of the sixth conductive portion 66 is between the position in the first direction of the eighth conductive portion 68 and the position in the first direction of the third electrode E3. For example, the direction from the eighth conductive portion 68 toward the seventh conductive portion 67 is along the Y-axis direction.

As shown in FIGS. 1A and 2D, the second nitride layer 12 includes a fourth region r4. The fourth region r4 is between the seventh conductive portion 67 and the eighth conductive portion 68. The fourth region r4 corresponds to a current path between the eighth conductive portion 68 and the first electrode E1. A lower contact resistance is obtained by such a configuration.

As shown in FIG. 1A, the center of the seventh conductive portion 67 in the third direction (e.g., the Y-axis direction) is taken as a seventh center 67c. The center of the fifth conductive portion 65 in the third direction is taken as a fifth center 65c. The center of the sixth conductive portion 66 in the third direction is taken as a sixth center 66c. The position in the third direction of the seventh center 67c is between the position in the third direction of the fifth center 65c and the position in the third direction of the sixth center 66c. For example, the third region r3 that corresponds to a current path is between the third electrode E3 and the seventh conductive portion 67. A lower contact resistance is obtained.

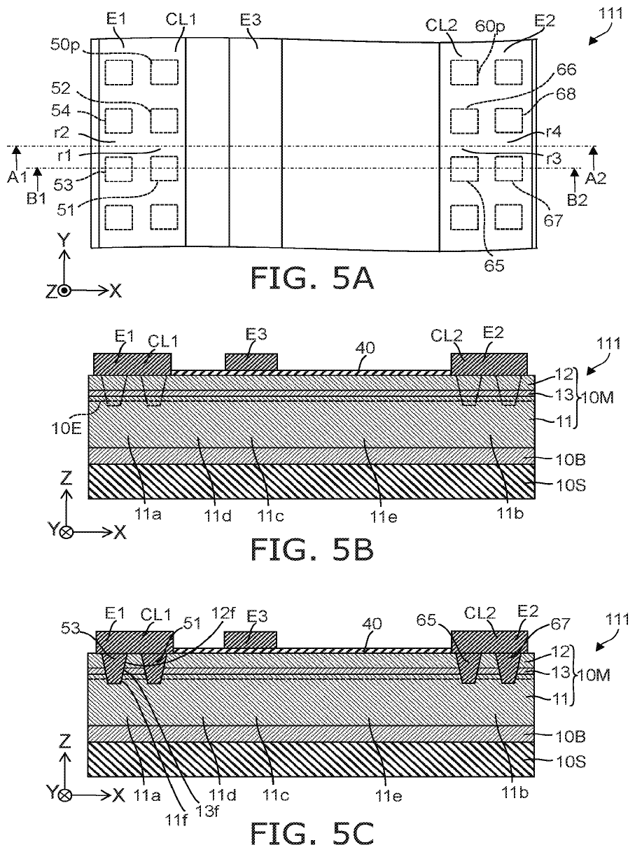

FIGS. 5A to 5C are schematic views illustrating a semiconductor device according to the first embodiment. FIG. 5A is a plan view. FIG. 5B is a line A1-A2 cross-sectional view of FIG. 5A. FIG. 5C is a line B1-B2 cross-sectional view of FIG. 5A.

As shown in FIGS. 5A to 5C, the semiconductor device 111 according to the embodiment also includes the first electrode E1, the second electrode E2, the third electrode E3, and the nitride member 10M. The first electrode E1 includes the multiple conductive portions 50p and the first conductive layer CL1. The second electrode E2 includes the multiple conductive portions 60p and the second conductive layer CL2. The arrangement of these conductive portions in the semiconductor device 111 is different from that of the semiconductor device 110. Otherwise, the configuration of the semiconductor device 111 is the same as the configuration of the semiconductor device 110.

In the semiconductor device 111 as shown in FIG. 5A, the direction from the third conductive portion 53 toward the first conductive portion 51 is along the first direction (the X-axis direction). For example, the direction from the fourth conductive portion 54 toward the second conductive portion 52 is along the first direction (the X-axis direction). In such a configuration as well, the current paths that are connected to the third and fourth conductive portions 53 and 54 can pass through at least a region (e.g., the first region r1) between the first conductive portion 51 and the second conductive portion 52, etc. A lower contact resistance is obtained. A lower on-resistance is obtained. A semiconductor device can be provided in which the characteristics can be improved.

In the semiconductor device 111 as shown in FIG. 5A, the direction from the fifth conductive portion 65 toward the seventh conductive portion 67 is along the first direction (the X-axis direction). The direction from the sixth conductive portion 66 toward the eighth conductive portion 68 is along the first direction (the X-axis direction). The current paths that are connected to the seventh and eighth conductive portions 67 and 68 can pass through at least a region (e.g., the third region r3) between the fifth conductive portion 65 and the sixth conductive portion 66, etc. A lower contact resistance is obtained. A lower on-resistance is obtained. A semiconductor device can be provided in which the characteristics can be improved.

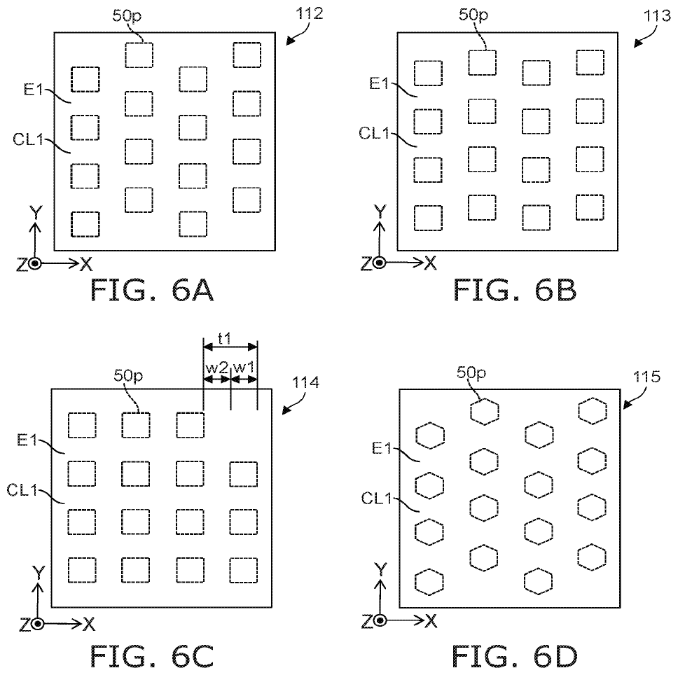

FIGS. 6A to 6D are schematic views illustrating semiconductor devices according to the first embodiment. These drawings illustrate the first electrode E1.

As shown in FIGS. 6A to 6D, in the semiconductor devices 112 to 115 as well, the first electrode E1 includes the multiple conductive portions 50p and the first conductive layer CL1. It is sufficient for the multiple conductive portions 50p to be arranged along the X-axis direction and the Y-axis direction.

In a semiconductor device 112 as shown in FIG. 6A, one conductive portion 50p does not overlap, in the X-axis direction, the conductive portion 50p that is adjacent in the X-axis direction. In a semiconductor device 113 as shown in FIG. 6B, one conductive portion 50p overlaps, in the X-axis direction, a portion of the conductive portion 50p that is adjacent in the X-axis direction. In a semiconductor device 114 as shown in FIG. 6C, one conductive portion 50p overlaps, in the X-axis direction, the conductive portion 50p that is adjacent in the X-axis direction.

In a semiconductor device 115 as shown in FIG. 6D, the planar shapes of the multiple conductive portions 50p are substantially hexagonal. The planar shape of one of the multiple conductive portions 50p may be any polygon or circle (including a flattened circle).

In the example of the semiconductor device 114 as shown in FIG. 6C, the length along the X-axis direction of one of the multiple conductive portions 50p is taken as a first length w1. The distance along the X-axis direction between the multiple conductive portions 50p is taken as a second length w2. When the first length w1 is long, for example, the region of the portion of one of the multiple conductive portions 50p that contacts the carrier region 10E is greater. When the second length w2 is long, the width of the current path between the multiple conductive portions 50p is greater. Practically, the first length w1 may be not less than 0.2 times and not more than 0.8 times the second length w2. In the embodiment, for example, the first length w1 may be not less than 0.4 times and not more than 0.6 times the second length w2. In the embodiment, the first length w1 may be substantially equal to the second length w2. For example, a stable and low contact resistance is easily obtained even when the manufacturing conditions fluctuate.

A pitch p1 in the X-axis direction of the multiple conductive portions 50p corresponds to the sum of the first length w1 and the second length w2. The pitch p1 is, for example, 10 μm or less.

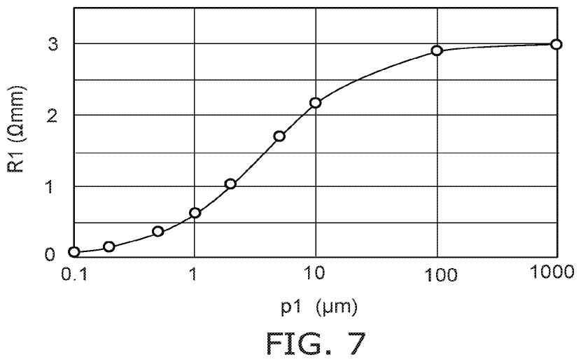

FIG. 7 is a graph illustrating a characteristic of the semiconductor device.

FIG. 7 illustrates simulation results of the change of the contact resistance of the first electrode E1 when changing the pitch p1 for the configuration of the semiconductor device 114. The horizontal axis of FIG. 7 is the logarithm of the pitch p1 (μm). The vertical axis of FIG. 7 is a contact resistance R1 (Ωmm) of the first electrode E1. In the simulation, the sheet resistance of the carrier region 10E is 400 Ω/square (Ω/□). The contact resistance was 1.5 Ωmm when the multiple conductive portions 50p were not provided (the semiconductor device 119a of the first reference example (referring to FIG. 4A)). The planar shapes of the multiple conductive portions 50p were squares. The length of one side of the multiple conductive portions 50p was equal to the distance between two mutually-adjacent conductive portions 50p.

As shown in FIG. 7, the resistance R1 starts to abruptly decrease when the pitch p1 becomes 10 μm or less.

In the embodiment, it is favorable for the pitch p1 to be 3.5 μm or less. A lower resistance than that of the first reference example is obtained thereby. It is more favorable for the pitch p1 to be 1 μm or less. A lower resistance is obtained.

Thus, in the embodiment, the first electrode E1 may include the multiple conductive portions 50p. The multiple conductive portions 50p includes the first to fourth conductive portions 51 to 54. It is favorable for the pitch p1 along the first direction (the X-axis direction) of the multiple conductive portions 50p to be 3.5 μm or less.

### Second Embodiment

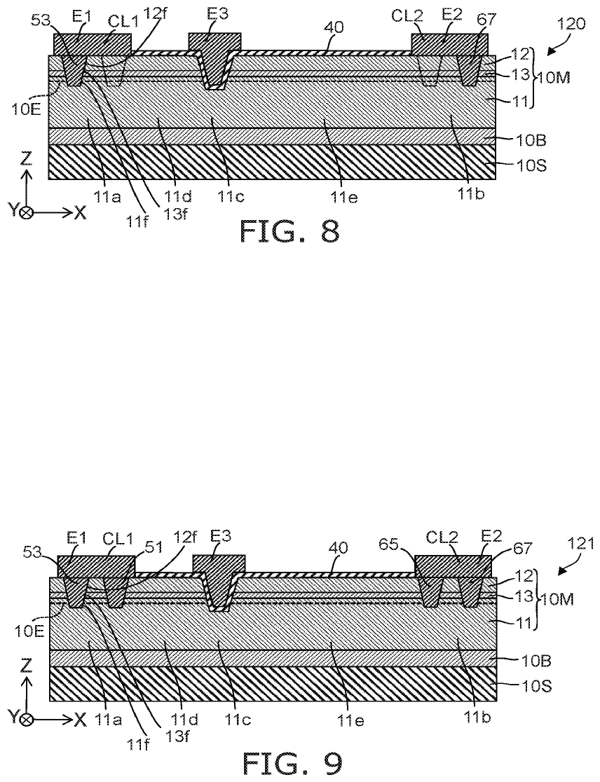

FIG. 8 is a schematic cross-sectional view illustrating a semiconductor device according to a second embodiment.

FIG. 8 is a cross-sectional view corresponding to a line A1-A2 of FIG. 1A.

As shown in FIG. 8, the configurations of the third electrode E3 and the insulating member 40 of the semiconductor device 120 according to the embodiment are different from those of the semiconductor device 110. Otherwise, the configuration of the semiconductor device 120 may be the same as the configuration of the semiconductor device 110.

FIG. 9 is a schematic cross-sectional view illustrating a semiconductor device according to the second embodiment.

FIG. 9 is a cross-sectional view corresponding to a line A1-A2 of FIG. 5A.

As shown in FIG. 9, the configurations of the third electrode E3 and the insulating member 40 of the semiconductor device 121 according to the embodiment are different from those of the semiconductor device 111. Otherwise, the configuration of the semiconductor device 121 may be the same as the configuration of the semiconductor device 111.

In the semiconductor devices 120 and 121, a portion of the third electrode E3 is buried in the nitride member 10M. For example, the direction from the third electrode E3 toward a portion of the first nitride layer 11 is along the first direction (the X-axis direction). The insulating member 40 is between the third electrode E3 and the nitride member 10M in the X-axis direction and the Y-axis direction.

For example, normally-off characteristics are obtained in the semiconductor devices 120 and 121. In the semiconductor device 120 as well, a low contact resistance of the first electrode E1 is obtained. A semiconductor device can be provided in which the characteristics can be improved.

In the embodiments described above, for example, at least one of the multiple conductive portions 50p or the multiple conductive portions 60p includes at least one selected from the group consisting of Ti, Al, TiN, Ni, and Au. At least one of the first conductive layer CL1 or the second conductive layer CL2 includes, for example, at least one selected from the group consisting of Ti, Al, TiN, Ni, and Au. The boundaries between the first conductive layer CL1 and the multiple conductive portions 50p may be distinct or indistinct. The boundaries between the second conductive layer CL2 and the multiple conductive portions 60p may be distinct or indistinct. The third electrode E3 includes, for example, at least one selected from the group consisting of Ti, TiN, Ni, and Al.

According to the embodiments, a semiconductor device can be provided in which the characteristics can be improved.

In the specification, “nitride semiconductor” includes all compositions of semiconductors of the chemical formula BₓIn_{y}Al_{z}Ga_{1-x-y-z}N (0≤x≤1, 0≤y≤1, 0≤z≤1, and x+y+z≤1) for which the composition ratios x, y, and z are changed within the ranges respectively. “Nitride semiconductor” further includes group V elements other than N (nitrogen) in the chemical formula recited above, various elements added to control various properties such as the conductivity type and the like, and various elements included unintentionally.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in semiconductor devices such as substrates, nitride members, nitride layers, electrodes, conductive portions, conductive layers, insulating members, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices practicable by an appropriate design modification by one skilled in the art based on the semiconductor devices described above as embodiments of the invention also are within the scope of the invention to the extent that the spirit of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a first electrode;
a second electrode;
a third electrode, a position of the third electrode in a first direction being between a position of the first electrode in the first direction and a position of the second electrode in the first direction, the first direction being from the first electrode toward the second electrode; and
a nitride member,
the nitride member including
a first nitride layer including Alₓ₁Ga₁₋ₓ₁N (0≤x1<1), the first nitride layer including a first partial region, a second partial region, and a third partial region, a direction from the first partial region toward the first electrode being along a second direction crossing the first direction, a direction from the second partial region toward the second electrode being along the second direction, a direction from the third partial region toward the third electrode being along the second direction, and
a second nitride layer including Alₓ₂Ga₁₋ₓ₂N (x1<x2<1),
the first electrode including a first conductive portion, a second conductive portion, a third conductive portion, and a first conductive layer,
the first conductive portion, the second conductive portion, the third conductive portion, and a portion of the second nitride layer being between the first partial region and the first conductive layer in the second direction,
the first conductive portion, the second conductive portion, and the third conductive portion being electrically connected to the first conductive layer,
a position in the first direction of the first conductive portion being between a position in the first direction of the third conductive portion and the position in the first direction of the third electrode,
a position in the first direction of the second conductive portion being between the position in the first direction of the third conductive portion and the position in the first direction of the third electrode,
the second nitride layer including a first region between the first conductive portion and the second conductive portion.

2. The device according to claim 1, wherein
the first conductive portion, the second conductive portion, and the third conductive portion are not electrically connected to a conductive member other than the first conductive layer.

3. The device according to claim 1, wherein
an other conductive member that contacts a region between the first nitride layer and the second nitride layer is not provided between the first conductive portion and the third electrode nor between the second conductive portion and the third electrode.

4. The device according to claim 1, wherein
the first conductive portion, the second conductive portion, and the third conductive portion are island-like.

5. The device according to claim 1, wherein
the first partial region includes a first side surface,
the first side surface crosses a third direction crossing a plane including the first and second directions, and
the first conductive portion contacts the first side surface.

6. The device according to claim 1, wherein
the portion of the second nitride layer includes a second side surface,
the second side surface crosses a third direction crossing a plane including the first and second directions, and
the first conductive portion contacts the second side surface.

7. The device according to claim 1, wherein
the nitride member further includes a third nitride layer including Alₓ₃Ga₁₋ₓ₃N (x2<x3≤1),
the third nitride layer is between the first nitride layer and the second nitride layer, and
the first conductive portion, the second conductive portion, and the third conductive portion extend through the third nitride layer along the second direction.

8. The device according to claim 7, wherein
the third nitride layer includes a third side surface,
the third side surface crosses a third direction crossing a plane including the first and second directions, and
the first conductive portion contacts the third side surface.

9. The device according to claim 1, wherein
the first partial region includes a first surface crossing the first direction,
a position of the first surface in the first direction is between the position of the third conductive portion in the first direction and the position of the third electrode in the first direction, and
the third conductive portion contacts the first surface.

10. The device according to claim 1, wherein
the portion of the second nitride layer includes a second surface crossing the first direction,
a position of the second surface in the first direction is between the position of the third conductive portion in the first direction and the position of the third electrode in the first direction, and
the third conductive portion contacts the second surface.

11. The device according to claim 1, wherein
the nitride member further includes a third nitride layer including Alₓ₃Ga₁₋ₓ₃N (x2<x3≤1),
the third nitride layer is between the first nitride layer and the second nitride layer,
the first conductive portion, the second conductive portion, and the third conductive portion extend through the third nitride layer in the second direction,
the third nitride layer includes a third surface crossing the first direction,
a position of the third surface in the first direction is between the position of the third conductive portion in the first direction and the position of the third electrode in the first direction, and
the third conductive portion contacts the third surface.

12. The device according to claim 1, wherein
a position in a third direction of a third-direction center of the third conductive portion is between a position in the third direction of a third-direction center of the first conductive portion and a position in the third direction of a third-direction center of the second conductive portion, and
the third direction crosses a plane including the first and second directions.

13. The device according to claim 1, wherein
a direction from the third conductive portion toward the first conductive portion is along the first direction.

14. The device according to claim 1, wherein
the first electrode further includes a fourth conductive portion electrically connected to the first conductive layer,
the fourth conductive portion is between the first partial region and the first conductive layer in the second direction,
a position in the first direction of the first conductive portion is between a position in the first direction of the fourth conductive portion and the position in the first direction of the third electrode,
a position in the first direction of the second conductive portion is between the position in the first direction of the fourth conductive portion and the position in the first direction of the third electrode, and
the second nitride layer includes a second region between the third conductive portion and the fourth conductive portion.

15. The device according to claim 14, wherein
the first electrode includes a plurality of conductive portions,
the plurality of conductive portions includes the first, second, third, and fourth conductive portions, and
a pitch along the first direction of the plurality of conductive portions is 3.5 μm or less.

16. The device according to claim 1, wherein
the second electrode includes a fifth conductive portion, a sixth conductive portion, a seventh conductive portion, and a second conductive layer,
the fifth conductive portion, the sixth conductive portion, the seventh conductive portion, and an other portion of the second nitride layer are between the second partial region and the second conductive layer in the second direction,
the fifth conductive portion, the sixth conductive portion, and the seventh conductive portion are electrically connected to the second conductive layer,
a position in the first direction of the fifth conductive portion is between a position in the first direction of the seventh conductive portion and the position in the first direction of the third electrode,
a position in the first direction of the sixth conductive portion is between the position in the first direction of the seventh conductive portion and the position in the first direction of the third electrode, and
the second nitride layer includes a third region between the fifth conductive portion and the sixth conductive portion.

17. The device according to claim 16, wherein
the nitride member further includes a third nitride layer including Alₓ₃Ga₁₋ₓ₃N (x2<x3≤1),
the third nitride layer is between the first nitride layer and the second nitride layer, and
the fifth conductive portion, the sixth conductive portion, and the seventh conductive portion extend through the third nitride layer along the second direction.

18. The device according to claim 16, wherein
a position in a third direction of a third-direction center of the seventh conductive portion is between a position in the third direction of a third-direction center of the fifth conductive portion and a position in the third direction of a third-direction center of the sixth conductive portion, and
the third direction crosses a plane including the first and second directions.

19. The device according to claim 16, wherein
a direction from the fifth conductive portion toward the seventh conductive portion is along the first direction.

20. The device according to claim 1, wherein
a direction from the third electrode toward a portion of the first nitride layer is along the first direction.
